(19) United States
(12) Patent Application Publication
(10) Pub. No.: US 2025/0336694 A1
(43) Pub. Date: Oct. 30, 2025

(54) SUBSTRATE PROCESSING APPARATUS AND SUBSTRATE PROCESSING METHOD

(71) Applicant: SHIBAURA MECHATRONICS CORPORATION, Yokohama-shi (JP)

(72) Inventors: Masaya KAMIYA, Yokohama-shi (JP); Kensuke DEMURA, Yokohama-shi (JP); Satoshi NAKAMURA, Yokohama-shi (JP)

(73) Assignee: SHIBAURA MECHATRONICS CORPORATION, Yokohama-shi (JP)

(21) Appl. No.: 19/188,406

(22) Filed: Apr. 24, 2025

(30) Foreign Application Priority Data
Apr. 25, 2024 (JP) 2024-071714
Mar. 27, 2025 (JP) 2025-053598

(51) Int. Cl. H01L 21/67; H01L 21/687

(52) U.S. Cl. CPC H01L 21/67051; H01L 21/67115; H01L 21/68764

(57) ABSTRACT

A substrate processing apparatus includes: a stage configured to rotate a substrate placed on the stage; a nozzle extending along a surface of the substrate; and a light source configured to irradiate ultraviolet rays to a raw material liquid flowing inside the nozzle.

### CROSS-REFERENCE TO RELATED APPLICATION

This application is based upon and claims the benefit of priority from Japanese Patent Applications Nos. 2024-071714 and 2025-053598, filed on Apr. 25, 2024 and Mar. 27, 2025, respectively, the entire contents of which are incorporated herein by reference.

### TECHNICAL FIELD

The present disclosure relates to a substrate processing apparatus and a substrate processing method.

### BACKGROUND

In the manufacture of semiconductor devices, the manufacture of photomasks, the manufacture of flat panel displays, and the like, a processing is performed to remove particles or organic substances adhering to the surface of a substrate.

For example, there has been proposed a technique of supplying ozone water to a surface of a substrate to which particles or organic substances adhere, thereby decomposing and removing the particles or organic substances. However, the removal using ozone water alone cannot obtain a sufficient removal effect.

Thus, there has been proposed a technique in which ozone water supplied to a surface of a substrate is irradiated with ultraviolet rays in related arts. By irradiating ozone water with ultraviolet rays, a processing liquid including OH radicals may be generated. When the processing liquid including OH radicals is used, particles or organic substances adhering to the surface of a substrate may be decomposed and removed using OH radicals.

However, when ozone water is supplied to the surface of the substrate and is irradiated with ultraviolet rays, there is a concern that the surface of the substrate will be oxidized and surface characteristics of the substrate will change. In addition, the ozone water supplied to the surface of the substrate is discharged in a relatively short period of time. Therefore, the accumulated amount of ultraviolet rays irradiated to the ozone water is small, which reduces the generation efficiency of OH radicals. In addition, it is difficult to make uniform the illuminance of ultraviolet rays irradiated to the ozone water on the surface of the substrate. Therefore, there is a concern that the amount of OH radicals generated may have an in-plane distribution. If the generation efficiency of OH radicals is low or an in-plane distribution occurs in the amount of OH radicals generated, there is a concern that proper processing of the substrate may not be performed. Therefore, there has been a demand for the development of a substrate processing apparatus and a substrate processing method capable of performing appropriate processing using a processing liquid including OH radicals.

### SUMMARY

Some embodiments of the present disclosure provide a substrate processing apparatus and a substrate processing method capable of performing an appropriate processing using a processing liquid including OH radicals.

According to one embodiment of the present disclosure, there is provided a substrate processing apparatus including: a stage configured to rotate a substrate placed on the stage; a nozzle extending along a surface of the substrate; and a light source configured to irradiate ultraviolet rays to a raw material liquid flowing inside the nozzle.

According to one embodiment of the present disclosure, there is provided a substrate processing method including: generating a processing liquid including OH radicals by irradiating ultraviolet rays to a raw material liquid flowing inside a flow path provided in a nozzle; and supplying the generated processing liquid to a surface of a substrate through a plurality of discharge ports being in communication with the flow path.

### BRIEF DESCRIPTION OF DRAWINGS

The accompanying drawings, which are incorporated in and constitute a part of the specification, illustrate embodiments of the present disclosure.

FIG. 1 is a schematic diagram illustrating a substrate processing apparatus according to an embodiment.

FIG. 2 is a schematic plan view of the substrate processing apparatus when viewed in the A-A line direction in FIG. 1.

FIG. 3 is a schematic perspective view illustrating a processing liquid generator.

FIG. 4 is a schematic perspective view of the processing liquid generator when viewed from the B direction in FIG. 3.

FIG. 5 is a schematic perspective view in which a cover and a light shielding cover are omitted from the processing liquid generator shown in FIG. 4.

FIG. 6 is a schematic perspective view of a nozzle as viewed from a light source.

FIG. 7 is a cross-sectional view of the nozzle taken along line C-C in FIG. 6.

FIG. 8 is a schematic perspective view illustrating a lid.

FIGS. 9A and 9B are schematic diagrams illustrating flow paths according to another embodiments.

FIG. 10 is a schematic diagram illustrating a flow path according to yet another embodiment.

FIG. 11 is a schematic perspective view illustrating a nozzle according to another embodiment.

FIG. 12 is a schematic perspective view illustrating a case in which a light shielding cover is provided around the nozzle shown in FIG. 11.

FIG. 13 is a graph illustrating generation of OH radicals by irradiation of ultraviolet rays.

FIG. 14 is a graph illustrating an effect of removal of a resist by a processing liquid including OH radicals.

FIG. 15 is a graph illustrating influence of the processing liquid including OH radicals on a surface of a substrate.

FIG. 16 is a graph illustrating an effect of removal of a foreign substance by the processing liquid including OH radicals.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments will be described with reference to the drawings. Throughout drawings, the same components are designated by the same reference numerals, and the detailed descriptions thereof are appropriately omitted.

Furthermore, the substrate 100 described below may be, for example, a semiconductor wafer, an imprint template, a photolithography mask, a plate-shaped body used in Micro Electro Mechanical Systems (MEMS), and the like. In addition, the substrate 100 is not limited to those exemplified above. The substrate 100 may be, for example, a substrate having a pattern (e.g., a fine uneven portion) formed on a surface of the substrate 100, or may be a so-called bulk substrate.

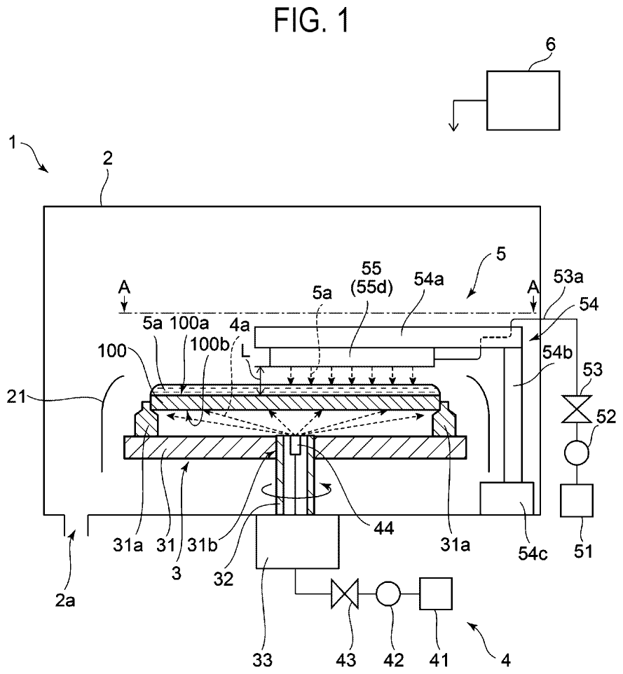

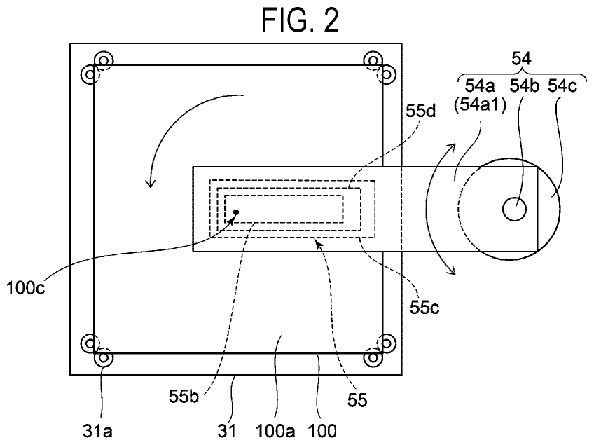

FIG. 1 is a schematic diagram illustrating a substrate processing apparatus 1 according to an embodiment. FIG. 2 is a schematic plan view of the substrate processing apparatus 1 when viewed in the A-A line direction in FIG. 1. In addition, although the substrate 100 having a square shape in a plan view is illustrated in FIG. 2, the shape of the substrate 100 in a plan view is not limited thereto. For example, the shape of the substrate 100 in a plan view may be a circular shape or the like. In FIG. 2, a processing liquid 5a supplied onto a front surface 100a of the substrate 100 of FIG. 1 is omitted from the illustration.

As shown in FIGS. 1 and 2, the substrate processing apparatus 1 includes, for example, a chamber 2, a stage 3, a liquid supply 4, a processing liquid supply 5, and a controller 6.

The controller 6 includes a calculator such as a CPU (Central Processing Unit) or the like, and a storage such as a memory or the like. The controller 6 may be, for example, a computer. The controller 6 controls the operation of each element provided in the substrate processing apparatus 1 based on a control program stored in the storage.

The chamber 2 has a box shape. The chamber 2 has an airtight structure that prevents, for example, particles in the ambient atmosphere from intruding into the chamber 2. Inside the chamber 2, a cover 21 surrounding the stage 3 (placement table 31) may be provided. The cover 21 receives a liquid 4a or the processing liquid 5a, which is supplied to a substrate 100 and discharged to the outside of the substrate 100 when the placement table 31 on which the substrate 100 is placed rotates. The used liquid 4a or the processing liquid 5a received by the cover 21 is discharged to factory piping or the like through, for example, an outlet 2a provided on a bottom surface of the chamber 2.

The stage 3 rotates the substrate 100 placed thereon. The stage 3 includes, for example, the placement table 31, a rotary shaft 32, and a drive 33. The placement table 31 has a plate shape and is rotatably provided inside the chamber 2. On one main surface (placement surface) of the placement table 31, a plurality of support portions 31a for supporting the substrate 100 is provided. When the substrate 100 is supported on the plurality of support portions 31a, a front surface 100a (target surface) of the substrate 100 faces a side opposite to the placement table 31. In addition, a hole 31b penetrating in a thickness direction of the placement table 31 is provided in the central portion of the placement table 31.

The rotary shaft 32 has a cylindrical shape. One end portion of the rotary shaft 32 on the placement table 31 side is provided on the placement table 31. An opening of a hole penetrating the rotary shaft 32 in an axial direction faces a rear surface 100b of the substrate 100 placed on the placement table 31. The other end portion of the rotary shaft 32 on aside opposite to the placement table 31 side may be provided outside the chamber 2.

The drive 33 is provided outside the chamber 2. The drive 33 is connected to the rotary shaft 32. A rotation force of the drive 33 is transmitted to the placement table 31 via the rotary shaft 32. Therefore, the placement table 31 and the substrate 100 placed on the placement table 31 can be rotated by the drive 33.

In addition, the drive 33 can change a rotation number (rotational speed) as well as the start and stop of rotation. The drive 33 may be provided with, for example, a control motor such as a servo motor.

The liquid supply 4 supplies the liquid 4a to the rear surface 100b of the substrate 100 placed on the placement table 31. The liquid supply 4 is provided to supply, for example, the liquid 4a that protects the rear surface 100b of the substrate 100. For example, the liquid supply 4 suppresses the processing liquid 5a supplied to the front surface 100a of the substrate 100 from intruding toward the rear surface 100b of the substrate 100 and adhering to the rear surface 100b of the substrate 100. In this case, the liquid 4a is not particularly limited as long as it does not easily react with the material of the substrate 100. The liquid 4a may be, for example, pure water.

In addition, the liquid supply 4 may also be provided for, for example, cleaning or processing the rear surface 100b of the substrate 100. In this case, the liquid 4a may be, for example, a cleaning liquid or a processing liquid. The liquid 4a may be, for example, a hydrogen peroxide solution, ozone water, pure water, an inorganic acid, an inorganic alkali, an organic acid, an organic alkali, electrolytic water, or a combination of two or more of them. In addition, the liquid 4a may also be a liquid including OH radicals, just like the processing liquid 5a described below.

The liquid supply 4 may be provided according to the need for protection, cleaning, processing, or the like of the rear surface 100b of the substrate 100, for example. Therefore, the liquid supply 4 is not necessarily required and may be omitted.

The liquid supply 4 includes, for example, a liquid accommodator 41, a supply 42, a flow rate controller 43, and a nozzle 44. The liquid accommodator 41, the supply 42 and the flow rate controller 43 are provided outside the chamber 2.

The liquid accommodator 41 accommodates the liquid 4a. The supply 42 is connected to the liquid accommodator 41 via a pipe. The supply 42 supplies the liquid 4a accommodated in the liquid accommodator 41 to the nozzle 44. The supply 42 may be, for example, a pump having resistance to the liquid 4a.

The flow rate controller 43 is connected to the supply 42 via a pipe. The flow rate controller 43 controls a flow rate of the liquid 4a supplied by the supply 42. The flow rate controller 43 may be, for example, a flow rate control valve. In addition, the flow rate controller 43 may also start and stop the supply of the liquid 4a.

The nozzle 44 is provided inside the hole of the rotary shaft 32. The nozzle 44 may be provided, for example, in a vicinity of the end portion of the rotary shaft 32 on the placement table 31 side. One end portion of the nozzle 44 is connected to the flow rate controller 43 through a pipe. The other end portion of the nozzle 44 has an injection port. The injection port of the nozzle 44 faces the rear surface 100b of the substrate 100 placed on the placement table 31. The spray pattern of the nozzle 44 may be, for example, a flat pattern, a full cone pattern, a curtain pattern, or the like. In addition, the spray pattern of the nozzle 44 illustrated in FIG. 1 is a flat pattern or a full cone pattern.

The processing liquid supply 5 generates the processing liquid 5a and supplies the generated processing liquid 5a to the front surface 100a of the substrate 100 placed on the placement table 31. The processing liquid 5a may be a liquid including OH radicals, which are active species.

The processing liquid supply 5 includes, for example, a raw material liquid accommodator 51, a supply 52, a flow rate controller 53, a mover 54, and a processing liquid generator 55. The raw material liquid accommodator 51, the supply 52, and the flow rate controller 53 may be provided outside the chamber 2. The mover 54 and the processing liquid generator 55 may be provided inside the chamber 2.

The raw material liquid accommodator 51 accommodates a raw material liquid used for generating the processing liquid 5a. That is, the raw material liquid is used for generating a liquid including OH radicals. The raw material liquid may be a liquid including hydrogen atoms and oxygen atoms, such as ozone water, hydrogen peroxide solution, or pure water. As described below, the processing liquid 5a is generated by irradiating the raw material liquid with ultraviolet rays. Therefore, in view of the efficiency of generation of the processing liquid 5a, the raw material liquid is preferably ozone water or hydrogen peroxide solution, and is more preferably ozone water.

The supply 52 is connected to the raw material liquid accommodator 51 through a pipe. The supply 52 supplies the raw material liquid accommodated in the raw material liquid accommodator 51 to the processing liquid generator 55. The supply 52 may be, for example, a pump having a resistance to the raw material liquid.

An inlet of the flow rate controller 53 is connected to the supply 52 via a pipe. An outlet of the flow rate controller 53 is connected to the processing liquid generator 55 (nozzle 55d) via a pipe 53a. The pipe 53a may be a deformable pipe formed of a fluorine resin such as PFA or the like. The flow rate controller 53 controls a flow rate of the raw material liquid supplied to the processing liquid generator 55 by the supply 52, and further the flow rate of the processing liquid 5a supplied to the front surface 100a of the substrate 100 from the processing liquid generator 55. The flow rate controller 53 may be, for example, a flow rate control valve. In addition, the flow rate controller 53 may also start and stop the supply of the raw material liquid and the processing liquid 5a.

The mover 54 moves the processing liquid generator 55 in a direction approximately parallel to the front surface 100a of the substrate 100, for example. As described above, the placement table 31 on which the substrate 100 is placed rotates. Therefore, a moving speed (peripheral velocity) of the front surface 100a of the substrate 100 is different in a central region of the substrate 100 and a peripheral region of the substrate 100. For that reason, the amount of the processing liquid 5a supplied per unit area is greater in the central region of the substrate 100 than in the peripheral region of the substrate 100. Therefore, processing unevenness easily occurs on the front surface 100a of the substrate 100.

In this case, by moving the processing liquid generator 55 in the direction approximately parallel to the front surface 100a of the substrate 100, it is possible to reduce the variation in the amount of the processing liquid 5a supplied per unit area, and consequently suppress the occurrence of processing unevenness on the front surface 100a of the substrate 100.

In this case, within a plane approximately parallel to the front surface 100a of the substrate 100, the processing liquid generator 55 may be moved along an arc-shaped trajectory or the processing liquid generator 55 may be moved along a linear trajectory. The mover 54 illustrated in FIGS. 1 and 2 moves the processing liquid generator 55 along an arc-shaped trajectory within a plane approximately parallel to the front surface 100a of the substrate 100.

The mover 54 includes, for example, an arm 54a, a support 54b, and a drive 54c. For example, the arm 54a extends in one direction along the front surface 100a of the substrate 100 above the substrate 100. One end portion of the arm 54a is provided on the support 54b. The other end portion of the arm 54a is provided on a side opposite to the support 54b with a rotation center 100c of the substrate 100 interposed between the one end portion and the other end portion of the arm 54a in a plan view. In addition, a cover 54al may be provided at an end portion of the arm 54a on a side opposite to the substrate 100.

The support 54b extends in a direction approximately perpendicular to the front surface 100a of the substrate 100 (the placement surface of the stage 3). One end portion of the support 54b may be provided above the substrate 100. The other end portion of the support 54b may be provided in a vicinity of a bottom surface of the chamber 2.

The drive 54c may be provided inside the chamber 2 or outside the chamber 2. The drive 54c illustrated in FIG. 1 is provided on the bottom surface of the chamber 2. The drive 54c includes a driving device such as a motor or an air cylinder, for example.

In addition, when moving the processing liquid generator 55 along the linear trajectory, for example, a guide mechanism such as a linear motion bearing may be provided instead of the support 54b.

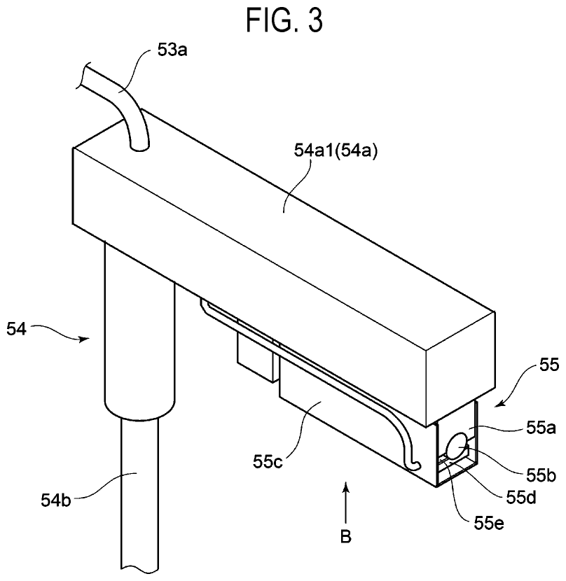

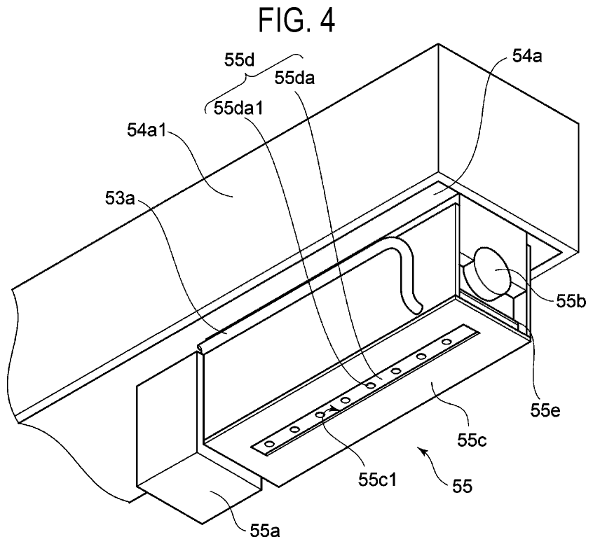

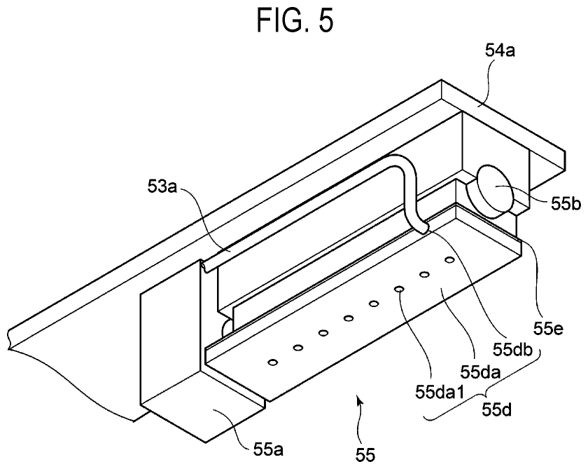

The processing liquid generator 55 may be provided at an end portion of the arm 54a on the stage 3 side. FIG. 3 is a schematic perspective view illustrating the processing liquid generator 55. FIG. 4 is a schematic perspective view of the processing liquid generator 55 as viewed from the B direction in FIG. 3. FIG. 5 is a schematic perspective view of the processing liquid generator 55 with the cover 54a1 and alight shielding cover 55c shown FIG. 4 omitted.

As shown in FIGS. 3 to 5, the processing liquid generator 55 includes, a holder 55a, a light source 55b, the light shielding cover 55c, a nozzle 55d, and a lid 55e.

The holder 55a holds, for example, the light source 55b. The holder 55a may be installed at an end portion of the arm 54a on the substrate 100 side using, for example, a fastening member such as a screw or the like. The holder 55a extends, for example, in a direction in which the arm 54a extends. In addition, a plurality of holders 55a may be provided at intervals, for example, in the direction in which the arm 54a extends.

The light source 55b is provided on the nozzle 55d on aside opposite to aside in which a plurality of discharge ports 55da1 of the nozzle 55d is opened. The light source 55b extends in a direction in which the nozzle 55d extends. The light source 55b irradiates ultraviolet rays to the raw material liquid flowing inside the nozzle 55d. The light source 55b irradiates ultraviolet rays having a wavelength of, for example, about 200 nm to 350 nm. The light source 55b is, for example, in a shape of a rod and has a cylindrical shape with a circular cross-section perpendicular to the longitudinal direction. The light source 55b may be, for example, a discharge lamp such as an excimer lamp or the like. In addition, the light source 55b may also be, for example, a light-emitting element such as a light-emitting diode or the like. When the light source 55b is a light-emitting element, a plurality of light-emitting elements may be provided side by side in the direction in which the arm 54a extends.

The light shielding cover 55c has, for example, a box shape and extends in the direction in which the arm 54a extends. Inside the light shielding cover 55c, the light source 55b, the lid 55e, and the nozzle 55d are accommodated. As described above, the light source 55b irradiates ultraviolet rays. In addition, as described later, the lid 55e and the nozzle 55d are formed of a material that transmits ultraviolet rays. Therefore, the light shielding cover 55c is provided to suppress ultraviolet rays irradiated from the light source 55b and ultraviolet rays irradiated from the light source 55b and transmitted through the lid 55e and the nozzle 55d from being irradiated to the outside of the processing liquid generator 55. The light shielding cover 55c may be formed of a material that does not transmit ultraviolet rays. The light shielding cover 55c may be formed of a metal such as stainless steel or an aluminum alloy, for example.

On a surface of the light shielding cover 55c facing the nozzle 55d, a hole 55c1 is provided through which the processing liquid 5a discharged from the plurality of discharge ports 55da1 of the nozzle 55d described later passes. The hole 55c1 has, for example, a slit shape extending in a direction in which the plurality of discharge ports 55da1 is arranged.

The light shielding cover 55c may be installed on the arm 54a or the holder 55a, for example, using a fastening member such as a screw or the like. In addition, in FIGS. 3 and 4, the light source 55b on aside of the other end portion of the arm 54a is not covered by the light shielding cover 55c. However, an end portion of the light source 55b may be covered by further providing a surface that intersects with respect to the direction in which the arm 54a extends and that is connected to a surface extending in the direction in which the arm 54a extends.

The nozzle 55d is provided, for example, on a side of the light source 55b opposite to the arm 54a. The nozzle 55d has a plate shape and extends along the front surface 100a of the substrate 100 (the placement surface of the stage 3). The nozzle 55d includes an outlet portion 55da that has, for example, a plate shape and extends in the direction in which the arm 54a extends, and an inlet portion 55db that is a hole opened on a side surface of the outlet portion 55da. In a direction in which the outlet portion 55da extends, the inlet portion 55db is provided in a vicinity of an end portion of the outlet portion 55da. The inlet portion 55db is connected to the raw material liquid accommodator 51 via the pipe 53a and the flow rate controller 53. The inlet portion 55db is provided to supply the raw material liquid to a flow path 55d1 of the nozzle 55d described later. The nozzle 55d (outlet portion 55da) is formed of a material that transmits ultraviolet rays, such as synthetic quartz glass or the like.

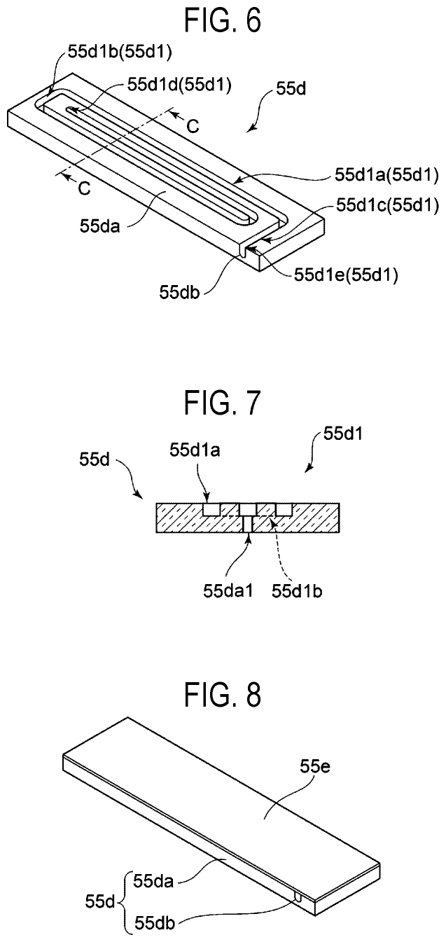

FIG. 6 is a schematic perspective view of the nozzle 55d as viewed from the light source 55b. FIG. 7 is a cross-sectional view of the nozzle 55d taken along line C-C in FIG. 6. As shown in FIGS. 6 and 7, one flow path 55d1 through which the raw material liquid flows is provided inside the nozzle 55d. The flow path 55d1 is opened on one surface of the nozzle 55d. The flow path 55d1 is, for example, in a groove shape, and has a shape that is curved so as to be wound. For example, the flow path 55d1 has a portion 55d1a that extends in the direction in which the outlet portion 55da extends, and a portion 55d1b that extends in a direction intersecting the direction in which the outlet portion 55da extends. For example, a plurality of portions 55d1a may be provided. The portion 55d1b brings an end portion of one portion 55d1a into communication with an end portion of another portion 55d1a. The portion 55d1c connects an end portion of one portion 55d1a and the inlet portion 55db.

One end portion of one flow path 55d1 is provided in the outlet portion 55da. In the direction intersecting the direction in which the outlet portion 55da extends, for example, one end portion of the portion 55d1a provided approximately at the center of the outlet portion 55da becomes one end portion 55d1d (terminal) of the one flow path 55d1. The other end portion of one flow path 55d1 is connected to the inlet portion 55db. For example, one end portion of the portion 55d1c connected to the inlet portion 55db becomes the other end portion 55d1e (terminal) of the one flow path 55d1.

In addition, as illustrated in FIGS. 5 and 7, the plurality of discharge ports 55da1 is in communication with the flow path 55d1 (portion 55d1a) provided approximately at the center of the outlet portion 55da. That is, the plurality of discharge ports 55da1 is in communication with the flow path 55d1 provided approximately at the center of the nozzle 55d (outlet portion 55da) in a direction intersecting the direction in which the nozzle 55d extends. The plurality of discharge ports 55da1 is opened on a surface of the nozzle 55d (outlet portion 55da) (a surface facing the front surface 100a of the substrate 100) which is opposite to a side on which the flow path 55d1 is opened. The plurality of discharge ports 55da1 is provided side by side in the direction in which the nozzle 55d (outlet portion 55da) extends.

The processing liquid 5a generated inside the flow path 55d1 of the nozzle 55d is supplied to the front surface 100a of the substrate 100 via the plurality of discharge ports 55da1. The number, arrangement, diameter, etc. of the plurality of discharge ports 55da1 may be appropriately changed according to the size of the substrate 100, the required flow rate of the processing liquid 5a, and the like. Details regarding the generation of the processing liquid 5a will be described later.

FIG. 8 is a schematic perspective view illustrating the lid 55e. As shown in FIG. 8, the lid 55e has a plate shape and covers the surface of the nozzle 55d on the side in which the flow path 55d1 is opened.

The shape of the lid 55e in a plan view may be the same as the shape of the nozzle 55d in a plan view. The lid 55e may be installed on the nozzle 55d using a fastening member such as a screw or the like, or may be bonded to the nozzle 55d. The lid 55e is formed of a material that transmits ultraviolet rays, such as synthetic quartz glass, for example.

Next, the generation of the processing liquid 5a and the processing of the substrate 100 using the processing liquid 5a will be described. First, the raw material liquid such as ozone water or the like accommodated in the raw material liquid accommodator 51 is supplied to the flow path 55d1 of the processing liquid 5a by the supply 52 and the flow rate controller 53. In addition, ultraviolet rays are irradiated from the light source 55b toward the nozzle 55d. The ultraviolet rays irradiated from the light source 55b penetrate the lid 55e and are irradiated onto the raw material liquid flowing inside the flow path 55d1. Since the nozzle 55d (outlet portion 55da) is also formed of a material that transmits ultraviolet rays, the ultraviolet rays incident on the nozzle 55d (outlet portion 55da) are irradiated from, for example, a side wall of the flow path 55d1 onto the raw material liquid flowing inside the flow path 55d1. Therefore, if the nozzle 55d (outlet portion 55da) is formed of a material that transmits ultraviolet rays, it is possible to improve the utilization efficiency of the ultraviolet rays irradiated from the light source 55b.

As described above, by the light source 55b, the raw material liquid is irradiated with ultraviolet rays through the nozzle 55d (lid 55e) to generate OH radicals. It is also conceivable to irradiate the raw material liquid with ultraviolet rays by bringing the raw material liquid into direct contact with the light source 55b. However, by irradiating the raw material liquid with ultraviolet rays through the nozzle 55d, the processing liquid 5a including OH radicals may be generated without mixing particles derived from the dust generation of the light source 55b into the raw material liquid.

By irradiating ultraviolet rays on the raw material liquid flowing inside one flow path 55d1, the processing liquid 5a including OH radicals is generated. For example, by irradiating ultraviolet rays on the raw material liquid, the raw material liquid is decomposed to generate OH radicals. Therefore, the processing liquid 5a including OH radicals is generated from the raw material liquid. The generated processing liquid 5a is supplied to the front surface 100a of the substrate 100 via the plurality of discharge ports 55da1 provided in the nozzle 55d. By supplying the processing liquid 5a including OH radicals to the front surface 100a of the substrate 100, particles or organic substances adhering to the front surface 100a of the substrate 100 are decomposed and removed.

As described above, the nozzle 55d extends along the front surface 100a of the substrate 100 (in a direction parallel to the front surface 100a of the substrate 100). The raw material liquid flowing inside the nozzle 55d is irradiated with ultraviolet rays by the light source 55b that irradiates ultraviolet rays. Therefore, compared to a case in which the nozzle 55d extends in a direction perpendicular to the front surface 100a of the substrate 100, it is possible to reduce the influence of gravity on the flow velocity of the raw material liquid flowing inside the nozzle 55d. When the influence of gravity on the flow velocity of the raw material liquid is reduced, it becomes easy to control the flow velocity of the raw material liquid by the supply pressure of the raw material liquid. In this case, by controlling the supply pressure of the raw material liquid to slow down the flow velocity of the raw material liquid, it is possible to lengthen the residence time of the raw material liquid in the flow path 55d1 extending along the light source 55b, and consequently increase the accumulated amount of ultraviolet rays irradiated onto the raw material liquid. Accordingly, it is possible to efficiently generate the processing liquid 5a including OH radicals.

In addition, as described above, the one flow path 55d1 provided in the nozzle 55d has a curved shape. Therefore, it is possible to increase an overall length of the flow path 55d1, thereby lengthening the time for the raw material liquid to pass through the flow path 55d1 and consequently increasing the accumulated amount of ultraviolet light irradiated on the raw material liquid. Thus, it is possible to efficiently generate the processing liquid 5a including OH radicals. The overall length or cross-sectional dimension of the flow path 55d1 can be appropriately changed according to the size of the substrate 100, the required flow rate of the processing liquid 5a, or the like.

Furthermore, as described above, the processing liquid 5a including the generated OH radicals is supplied to the front surface 100a of the substrate 100 through the plurality of discharge ports 55da1. In addition, the plurality of discharge ports 55da1 is arranged along the direction in which the nozzle 55d extends. Therefore, as illustrated in FIG. 1, it is possible to simultaneously supply the processing liquid 5a to a wide region of the front surface 100a of the substrate 100.

OH radicals are easily deactivated. Therefore, for example, when the processing liquid 5a including OH radicals is supplied to the front surface 100a of the substrate 100 from one discharge port 55da1, the concentrations of OH radicals are different at a position immediately below the discharge port 55da1 and at a position spaced apart from the discharge port 55da1. M ore specifically, on the front surface 100a of the substrate 100, OH radicals are easily deactivated at the position spaced apart from the discharge port 55da1 than at the position immediately below the discharge port 55da1, thereby decreasing the concentration of OH radicals in the processing liquid 5a and weakening the removal effect of organic substances or the like. Asa result, the in-plane distribution easily occurs in the removal effect of organic substances or the like.

In this case, when the processing liquid 5a including OH radicals is supplied from the plurality of discharge ports 55da1 to the front surface 100a of the substrate 100 as illustrated in FIG. 1, it is possible to suppress the occurrence of an in-plane distribution in the concentration of OH radicals on the front surface 100a of the substrate 100. Accordingly, it is possible to suppress the occurrence of an in-plane distribution in the removal effect of organic substances or the like.

In addition, since the OH radicals are easily deactivated as described above, it is preferable for a distance L between the nozzle 55d and the front surface 100a of the substrate 100 to be 12 mm or less as shown in FIG. 1. By doing so, the deactivation of OH radicals is suppressed, thereby improving the removal efficiency of organic substances or the like.

In addition, the processing liquid 5a supplied to the front surface 100a of the substrate 100 is discharged to the outside of the substrate 100 as the substrate 100 rotates. Therefore, the residence time of the processing liquid 5a supplied to the peripheral region of the substrate 100 becomes shorter than the residence time of the processing liquid 5a supplied to the central region of the substrate 100. Thus, a flow rate of the processing liquid 5a supplied to the peripheral region of the substrate 100 may be made larger than a flow rate of the processing liquid 5a supplied to the central region of the substrate 100. For example, a pitch dimension of the discharge port 55da1 facing the peripheral region of the substrate 100 may be made shorter than a pitch dimension of the discharge port 55da1 facing the central region of the substrate 100. Additionally, for example, an opening area of the discharge port 55da1 facing the peripheral region of the substrate 100 may be made larger than an opening area of the discharge port 55da1 facing the central region of the substrate 100.

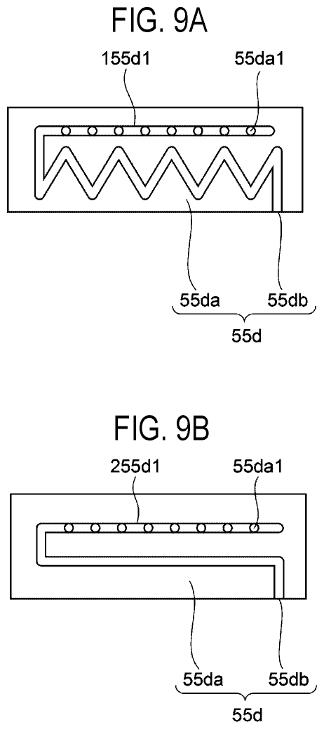

FIGS. 9A and 9B are schematic diagrams illustrating flow paths 155d1 and 255d1 according to another embodiments. As illustrated in FIG. 9A, one flow path 155d1 has a meandering shape in the direction in which the outlet portion 55da extends. As illustrated in FIG. 9B, one flow path 255d1 has a meandering shape in the direction intersecting the direction in which the outlet portion 55da extends.

Since the total length of one flow path 155d1 or 255d1 may be lengthened in this way, it is possible to lengthen the time for the raw material liquid to pass through the flow path 155d1 or 255d1, and consequently increase the accumulated amount of ultraviolet light irradiated on the raw material liquid. Accordingly, it is possible to efficiently generate the processing liquid 5a including OH radicals.

As illustrated in FIG. 6, if one flow path 55d1 has a shape that is curved so as to be wound, the plurality of discharge ports 55da1 may be provided in the flow path 55d1 (portion 55d1a) provided approximately at the center of the outlet portion 55da. In this case, as illustrated in FIG. 5, the light source 55b faces the flow path 55d1 (portion 55d1a) provided approximately at the center of the outlet portion 55da. The light source 55b has a cylindrical shape and extends in the direction in which the nozzle 55d (outlet portion 55da) extends, and is arranged so that the axis of the light source 55b is located in a region facing the approximate center of the outlet portion 55da. Therefore, it is possible to reduce the distance between the flow path 55d1 (portion 55d1a) provided approximately at the center of the outlet portion 55da and the surface (irradiation surface) of the light source 55b. Accordingly, since the illuminance of ultraviolet rays irradiated on the flow path 55d1 (portion 55d1a) having a plurality of discharge ports 55da1 may be increased, it is possible to increase the generation efficiency of OH radicals, and increase the concentration of OH radicals included in the processing liquid 5a immediately before being supplied to the front surface 100a of the substrate 100. If the concentration of OH radicals included in the processing liquid 5a immediately before being supplied to the front surface 100a of the substrate 100 may be increased, it is possible to improve the removal efficiency of organic substances or the like.

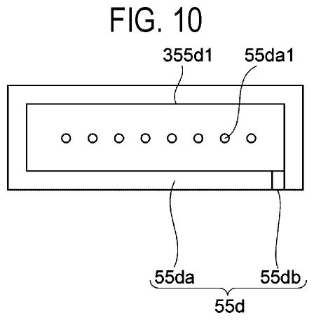

FIG. 10 is a schematic diagram illustrating a flow path 355d1 according to yet another embodiment. The dimension of the flow path 355d1 shown in FIG. 10 in a direction orthogonal to the direction in which the outlet portion 55da extends may be made larger than, for example, the width dimension of the light source 55b. As shown in FIG. 10, a volume of a portion of the flow path 355d1 that extends in the direction in which the outlet portion 55da extends may be made larger. By doing so, it is possible to lengthen the residence time of the raw material liquid in the flow path 355d1, and consequently increase the accumulated amount of ultraviolet light irradiated to the raw material liquid. Accordingly, it is possible to efficiently generate the processing liquid 5a including OH radicals can be efficiently generated.

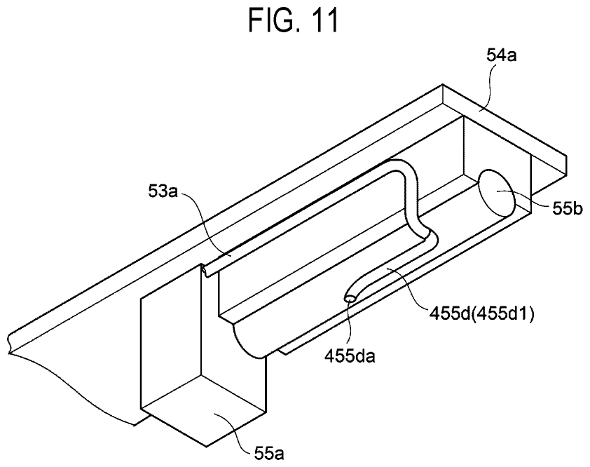

FIG. 11 is a schematic perspective view illustrating a nozzle 455d according to another embodiment. As illustrated in FIG. 11, the nozzle 455d has a tubular shape. A n interior of the tubular nozzle 455d becomes a flow path 455d1 through which the raw material liquid flows. The nozzle 455d has a portion facing the light source 55b, and the facing portion extends along the light source 55b. The portion of the nozzle 455d facing the light source 55b is formed of a material that transmits ultraviolet rays, such as synthetic quartz glass. Therefore, the ultraviolet rays irradiated from the light source 55b are incident on the raw material liquid flowing through the flow path 455d1 inside the nozzle 455d. When the ultraviolet rays are irradiated on the raw material liquid flowing through the flow path 455d1, a processing liquid 5a including OH radicals is generated.

One end portion of the nozzle 455d is connected to the pipe 53a. The pipe 53a may be a deformable pipe formed of a fluorine resin such as PFA or the like. The other end portion of the nozzle 455d is opened. The raw material liquid flowing inside the nozzle 455d (flow path 455d1) is irradiated with ultraviolet rays, thereby generating the processing liquid 5a, which is supplied to the front surface 100a of the substrate 100 from an opening 455da of the nozzle 455d. By supplying the processing liquid 5a including OH radicals to the front surface 100a of the substrate 100, particles and organic substances adhering to the front surface 100a of the substrate 100 are decomposed and removed.

As described above, in this embodiment, the deformable pipe 53a is connected to one end portion of the nozzle 455d having the tubular shape. Therefore, compared to the nozzle 55d having a plate shape and having a flow path therein, the location for arranging the nozzle 455d (flow path 455d1) may be freely selected.

In addition, it is possible to lengthen the straight distance of the flow path 455d1 onto which ultraviolet rays from the light source 55b are incident. If the flow path 455d1 extends along a straight line, it is possible to suppress the generated OH radicals from colliding with the curved flow path and being deactivated. Accordingly, it becomes easy to supply the processing liquid 5a including OH radicals to the front surface 100a of the substrate 100. Additionally, if the straight line distance of the flow path 455d1 is long, it is possible to increase the amount of OH radicals generated.

In addition, it is conceivable to bring the raw material liquid into direct contact with the light source 55b to directly irradiate the raw material liquid with ultraviolet rays. However, there is a concern that particles derived from the dust generation of the light source 55b may be mixed into the raw material liquid. If the raw material liquid is irradiated with ultraviolet rays through the nozzle 455d, it is possible to suppress particles derived from the dust generation of the light source 55b from being mixed into the raw material liquid. Accordingly, it is possible to supply the processing liquid 5a without foreign substances to the front surface 100a of the substrate 100.

In addition, the nozzle 455d extends along the front surface 100a of the substrate 100 (in the direction parallel to the front surface 100a of the substrate 100). Therefore, compared to a case in which the nozzle 455d extends in the direction perpendicular to the front surface 100a of the substrate 100, it is possible to reduce the influence of gravity on the flow velocity of the raw material liquid flowing through the flow path 455d1 inside the nozzle 455d. When the influence of gravity on the flow velocity of the raw material liquid is reduced, it becomes easy to control the flow velocity of the raw material liquid by the supply pressure.

In this case, by controlling the supply pressure of the raw material liquid to slow down the flow velocity of the raw material liquid, it is possible to lengthen the residence time of the raw material liquid in the flow path 455d1 extending along the light source 55b, and consequently increase the accumulated amount of ultraviolet rays irradiated on the raw material liquid. Accordingly, it is possible to efficiently generate the processing liquid 5a including OH radicals.

In addition, in FIG. 11, the nozzle 455d is arranged so that the raw material liquid flows from the other end portion side of the arm 54a toward the support 54b of the arm 54a. However, the nozzle 455d may be arranged so that the raw material liquid flows from the support 54b of the arm 54a toward the other end portion side of the arm 54a. There is no particular limitation on the arrangement of the nozzle 455d, as long as the opening 455da of the nozzle 455d is located above the center of the substrate 100.

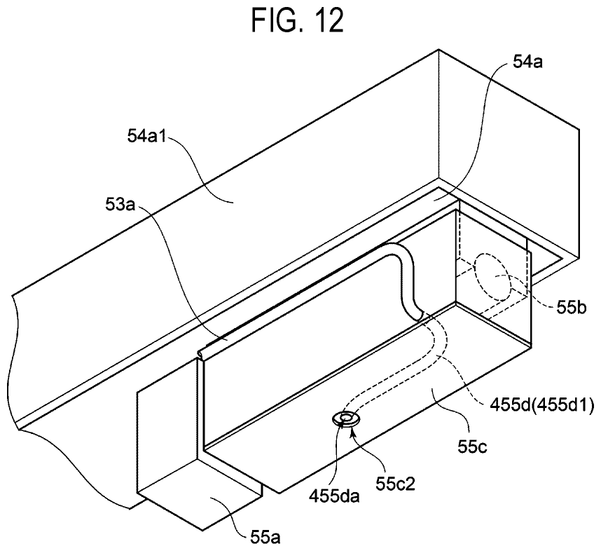

FIG. 12 is a schematic perspective view illustrating a case in which the light shielding cover 55c is provided around the nozzle 455d shown in FIG. 11. As shown in FIG. 12, the light shielding cover 55c may be provided to surround the light source 55b. When the light shielding cover 55c is provided, the ultraviolet rays irradiated from the light source 55b and the ultraviolet rays irradiated from the light source 55b and transmitted through the nozzle 455d may be suppressed from being irradiated to the outside of the processing liquid generator 55.

Furthermore, a hole 55c2 through which the processing liquid 5a discharged from the opening 455da of the nozzle 455d passes may be provided on the surface of the light shielding cover 55c that faces the nozzle 455d and the front surface 100a of the substrate 100. The dimension of the hole 55c2 may be made larger than the dimension of the opening 455da of the nozzle 455d, for example. In the light shielding cover 55c shown in FIG. 12, the surface that faces the nozzle 455d and the front surface 100a of the substrate 100 may be omitted. In this case, the light shielding cover 55c is configured by a side wall provided to intersect the direction in which the arm 54a extends and configured to surround the light source 55b, and the portion that faces the front surface 100a of the substrate 100 is opened. From this opening, the light source 55b and the opening 455da of the nozzle 455d are exposed.

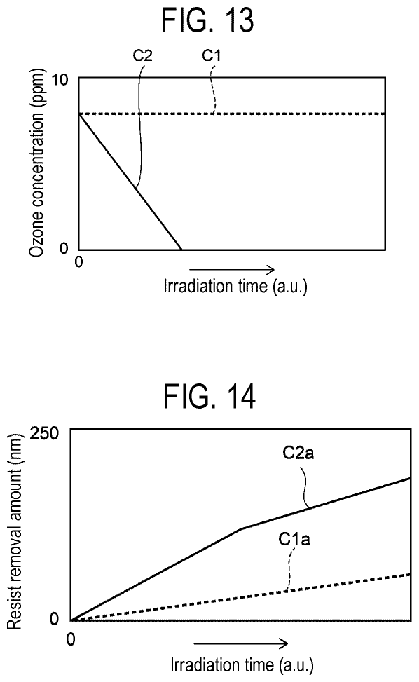

FIG. 13 is a graph illustrating the generation of OH radicals by the irradiation of ultraviolet rays. C1 in FIG. 13 indicates a case in which ozone water is not irradiated with ultraviolet rays. In this case, the decomposition of ozone (the generation of OH radicals) by irradiation of ultraviolet rays is not performed. Therefore, there is no change in ozone concentration.

C2 in FIG. 13 indicates a case in which ozone water is irradiated with ultraviolet rays having a wavelength range of 200 nm to 350 nm. In this case, ozone is decomposed by the irradiation of ultraviolet rays to generate OH radicals. Therefore, as the irradiation time elapses, the ozone concentration decreases, and the OH radical concentration increases accordingly. In other words, the concentration of OH radicals is positively correlated with the accumulated amount of ultraviolet rays. Therefore, if the relationship between the concentration of OH radicals and the accumulated amount of ultraviolet rays is obtained through experiments or simulations, it is possible to set, for example, the total length or cross-sectional area of one flow path 55d1 described above.

FIG. 14 is a graph illustrating the effect of removal of a resist by the processing liquid 5a including OH radicals. That is, FIG. 14 is an example of the effect of removal of an organic substance by the processing liquid 5a including OH radicals.

C1a in FIG. 14 indicates a case in which ozone water is not irradiated with ultraviolet rays, i.e., a case in which a resist is removed by the oxidation action of ozone water.

C2a in FIG. 14 indicates a case in which ozone water is irradiated with ultraviolet rays having a wavelength range of 200 nm to 350 nm. That is, this is a case in which the resist is removed by the processing liquid 5a including OH radicals. As can be seen from C1a in FIG. 14, the resist can be removed even if ozone water is used. However, as can be seen from C2a in FIG. 14, the use of the processing liquid 5a including OH radicals can significantly improve the removal efficiency of the resist.

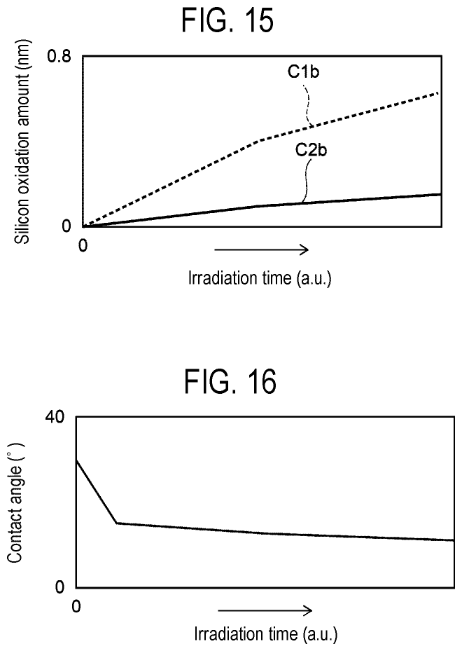

FIG. 15 is a graph illustrating the influence of the processing liquid 5a including OH radicals on the front surface 100a of the substrate 100.

C1b in FIG. 15 indicates a case in which no ultraviolet ray irradiation is performed on ozone water. That is, C1b indicates the oxidation amount of the front surface 100a of the substrate 100 (the oxidation amount of silicon) due to the oxidation action of ozone water.

C2a in FIG. 15 indicates a case in which ozone water is irradiated with ultraviolet rays having a wavelength range of 200 nm to 350 nm. That is, C2a indicates the oxidation amount of the front surface 100a of the substrate 100 (the oxidation amount of silicon) due to OH radicals. As can be seen from FIG. 15, when the processing liquid 5a including OH radicals is used, the oxidation amount on the front surface 100a of the substrate 100 can be reduced compared to a case in which ozone water is used.

That is, as can be seen from FIGS. 14 and 15, when the processing liquid 5a including OH radicals is used, it is possible to improve the removal efficiency of organic substances, and to suppress the damage to the front surface 100a of the substrate 100 compared to a case in which ozone water is used.

FIG. 16 is a graph illustrating the effect of removing foreign substances by the processing liquid 5a including OH radicals. If foreign substances such as particles are adhering to the front surface 100a of the substrate 100, the contact angle of the front surface 100a of the substrate 100 increases. In addition, as the cleanliness of the front surface 100a of the substrate 100 increases, the contact angle of the front surface 100a of the substrate 100 decreases.

As can be seen from FIG. 16, when the processing liquid 5a including OH radicals is supplied to the front surface 100a of the substrate 100, the contact angle of the front surface 100a of the substrate 100 can be reduced. That is, when the processing liquid 5a including OH radicals is supplied to the front surface 100a of the substrate 100, foreign substances such as particles adhering to the front surface 100a of the substrate 100 can be removed to clean the front surface 100a of the substrate 100.

Next, a substrate processing method according to the present embodiment is exemplified. The substrate processing method according to the present embodiment processes the substrate 100 as follows. First, ultraviolet rays are irradiated on the raw material liquid flowing inside the flow path 55d1 provided inside the nozzle 55d, thereby generating the processing liquid 5a including OH radicals. Then, the generated processing liquid 5a is supplied to the front surface 100a of the substrate 100 through the plurality of discharge ports 55da1 connected to the flow path 55d1.

In this case, the plurality of discharge ports 55da1 is arranged side by side in a direction approximately parallel to the front surface 100a of the substrate 100. In addition, since the specific details of the substrate processing method may be the same as described above, the detailed description thereof is omitted.

The embodiments have been exemplified above. However, the present disclosure is not limited to this technique. Even if a person skilled in the art appropriately adds or deletes components, changes the design of components, adds or omits processes, or changes conditions of processes in the above-described embodiments, such modifications are included in the scope of the present disclosure as long as they have the characteristics of the present disclosure.

For example, the shapes, dimensions, materials, arrangements, and the like of the respective elements of the substrate processing apparatus 1 are not limited to those exemplified and may be appropriately changed. In addition, the respective elements of the above-described embodiments may be combined as much as possible, and such combinations of elements are also included in the scope of the present disclosure as long as they include the features of the present disclosure.

According to the present disclosure in some embodiments, it is possible to provide a substrate processing apparatus and a substrate processing method capable of performing appropriate processing using a processing liquid including OH radicals.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a stage configured to rotate a substrate placed on the stage;
a nozzle extending along a surface of the substrate; and
a light source configured to irradiate ultraviolet rays to a raw material liquid flowing inside the nozzle.

2. The substrate processing apparatus of claim 1, wherein the nozzle has a plate shape, and includes:
one flow path provided inside the nozzle, having a curved shape, and configured to flow the raw material liquid inside the flow path; and
a plurality of discharge ports arranged side by side along a direction in which the nozzle extends, each of the plurality of discharge ports having one end portion kept in communication with the flow path and the other end portion opened on a surface of the nozzle facing the surface of the substrate.

3. The substrate processing apparatus of claim 2, wherein a processing liquid including OH radicals is generated by irradiating the raw material liquid flowing inside the flow path with the ultraviolet rays, and
wherein the generated processing liquid is supplied to the surface of the substrate through the plurality of discharge ports.

4. The substrate processing apparatus of claim 2, wherein the light source is provided on the nozzle on a side opposite to a side in which the plurality of discharge ports is opened, and extends in the direction in which the nozzle extends.

5. The substrate processing apparatus of claim 2, wherein the plurality of discharge ports is in communication with the flow path provided approximately at a center of the nozzle in a direction intersecting the direction in which the nozzle extends.

6. A substrate processing method comprising:
generating a processing liquid including OH radicals by irradiating ultraviolet rays to a raw material liquid flowing inside a flow path provided in a nozzle; and
supplying the generated processing liquid to a surface of a substrate through a plurality of discharge ports being in communication with the flow path.

7. The substrate processing method of claim 6, wherein the plurality of discharge ports is arranged side by side in a direction approximately parallel to the surface of the substrate.
